(19) United States
(12) Patent Application Publication
(10) Pub. No.: US 2018/0182916 A1
(43) Pub. Date: Jun. 28, 2018

(54) GROUP III NITRIDE SEMICONDUCTOR LIGHT-EMITTING DEVICE AND PRODUCTION METHOD THEREFOR

(71) Applicant: Toyoda Gosei Co., Ltd., Kiyosu-shi (JP)

(72) Inventors: Yoshiki Saito, Kiyosu-shi (JP); Daisuke Shinoda, Kiyosu-shi (JP)

(21) Appl. No.: 15/847,648

(22) Filed: Dec. 19, 2017

(30) Foreign Application Priority Data
Dec. 26, 2016 (JP) 2016-252006

(51) Int. Cl. H01L 33/00; H01L 33/32

(52) U.S. Cl. CPC H01L 33/0075; H01L 33/32

(57) ABSTRACT

To provide a Group III nitride semiconductor light-emitting device in which a semiconductor layer is grown using a substrate containing Al such as AlN substrate while suppressing polarity inversion, and a production method therefor. The light-emitting device includes a substrate, a first oxide film formed in contact with the substrate, a first Group III nitride layer formed in contact with the first oxide film, a second oxide film formed in contact with the first Group III nitride layer, and an n-type contact layer on the second oxide film. The substrate is an AlN substrate or AlGaN substrate. The first oxide film contains Al atoms, N atoms, and O atoms. The first Group III nitride layer comprises AlN or AlGaN. The second oxide film contains Al atoms, N atoms, and O atoms.

### BACKGROUND OF THE INVENTION

### Field of the Invention

The present techniques relate to a Group III nitride semiconductor light-emitting device and production method therefor.

### Background Art

When a semiconductor device having a Group III nitride semiconductor layer is produced, an AlN film is formed on a sapphire substrate in some cases. In that case, many threading dislocations are generated. The crystallinity of the semiconductor layer with high threading dislocation density is not so high.

Therefore, a template substrate produced through Hydride Vapor Phase Epitaxy (HVPE) or a free-standing bulk substrate has been employed in recent years. However, needless to say, these substrates are taken out from the production device after the production. At that time, an oxide film is formed on the surface of the substrate. Such oxide film may cause various problems on the semiconductor layer being formed on the top layer of the substrate.

The effect of oxidation of the AlN substrate will be described below.

Firstly, the case where the AlN substrate is not oxidized will be described. In the case where there are no oxygen atoms, a pair of a plane on which Al atoms are distributed and a plane on which N atoms are distributed is repeatedly arranged in a c-axis direction.

Subsequently, the case where the top surface of the AlN substrate is naturally oxidized by the atmosphere will be described. Parts of N atoms are replaced with oxygen atoms through natural oxidation of the surface of the AlN substrate. That is, AlON is partially formed on the substrate through oxidation of AlN. When oxygen atoms enter AlN, for example, —Al—N—Al—O—Al—O— bond is formed along the c-axis direction. This Al—O—Al bond inverts the polarity. In a semiconductor layer being grown on the top layer of the substrate, a portion where Group III polar surface is dominant and a portion where nitrogen polar surface is dominant are generated on account of partial oxidation. As a result, the crystallinity of the semiconductor layer being grown on the substrate is relatively low. Moreover, the impurity concentration of such semiconductor layer is relatively high. It is difficult to produce a high performance semiconductor light-emitting device. The techniques to improve the crystallinity of the AlN film are disclosed in, for example, Japanese Patent Application Laid-Open (kokai) No. 2015-42598.

### SUMMARY OF THE INVENTION

The present techniques have been conceived to solve the aforementioned problems involved in conventional techniques. Thus, an object of the present techniques is to provide a Group III nitride semiconductor light-emitting device in which a semiconductor layer is grown using a substrate containing Al such as AlN substrate while suppressing partial inversion of the polarity of the semiconductor layer, and a production method therefor.

In the first aspect of the present invention, there is provided a Group III nitride semiconductor light-emitting device, the light-emitting device including a substrate, a first oxide film formed in contact with the substrate, a first Group III nitride layer formed in contact with the first oxide film, a second oxide film formed in contact with the first Group III nitride layer, a first conductive type first semiconductor layer formed on the second oxide film, a light-emitting layer formed on the first semiconductor layer, a second conductive type second semiconductor layer formed on the light-emitting layer. The substrate is an AlN substrate or AlGaN substrate. The first oxide film contains Al atoms, N atoms, and O atoms. The first Group III nitride layer comprises AlN or AlGaN. The second oxide film contains Al atoms, N atoms, and O atoms.

The Group III nitride semiconductor light-emitting device has the first oxide film, the first Group III nitride layer, and the second oxide film on the AlN substrate or the AlGaN substrate. The first oxide film and the second oxide film which are uniformly and completely oxidized invert the polarity of the lower layer. Therefore, in one semiconductor layer, coexistence of a portion where Group III polarity III is dominant and a portion where nitrogen polarity is dominant are hardly generated. Thus, a semiconductor layer superior in crystallinity and impurity concentration can be grown.

In the present invention the first oxide film may be an oxidized surface of the substrate and the second oxide film may be an oxidized surface of the first Group III nitride layer. The polarity of the first conductive type first semiconductor layer is equal to the polarity of the substrate. The substrate may be made of AlN and the first Group III nitride layer may be made of AlN. In the case the first oxide film is made of AlON, and the second oxide film is made of AlON. Each thickness of the first oxide film and the second oxide film is preferably in a range from 3 nm to 100 nm. An Al composition ratio of the first Group III nitride layer is preferably not smaller than 0.5. An Al composition ratio of the first conductive type first semiconductor layer is preferably not smaller than 0.5.

In the second aspect of the present techniques, there is provided a method for producing a Group III nitride semiconductor light-emitting device, the method comprising a first oxide film formation step of forming a first oxide film on a substrate; a first Group III nitride layer formation step of forming a first Group III nitride layer on the first oxide film; a second oxide film formation step of forming a second oxide film on the first Group III nitride layer; a first semiconductor layer formation step of forming a first conductive type first semiconductor layer on the second oxide film; a light-emitting layer formation step of forming a light-emitting layer on the first semiconductor layer; and a second semiconductor layer formation step of forming a second conductive type second semiconductor layer on the light-emitting layer. In the production method, an AlN substrate or AlGaN substrate is employed as the substrate. In the first oxide film formation step, an oxide film containing Al atoms, N atoms, and O atoms is formed as the first oxide film. In the first Group III nitride layer formation step, an AlN layer or AlGaN layer is formed as the first Group III nitride layer. In the second oxide film formation step, an oxide film containing Al atoms, N atoms, and O atoms is formed as the second oxide film.

The present techniques, disclosed in the specification, provide a Group III nitride semiconductor light-emitting device in which a semiconductor layer is grown using a substrate containing Al such as AlN substrate while suppressing polarity inversion and a production method therefor.

### BRIEF DESCRIPTION OF THE DRAWINGS

Various other objects, features, and many of the attendant advantages of the present techniques will be readily appreciated as the same becomes better understood with reference to the following detailed description of the preferred embodiments when considered in connection with the accompanying drawings, in which:

FIG. 1 is a schematic view of the structure of a light-emitting device according to a first embodiment;

FIG. 2 is an enlarged view of the periphery of oxide film in the light-emitting device according to the first embodiment; and

FIG. 3 is a schematic view of the structure of a light-emitting device according to a variation of the first embodiment.

### DETAILED DESCRIPTION OF PREFERRED EMBODIMENT

With reference to the drawings, specific embodiments of the semiconductor light-emitting device of the present technique and the production method therefor will next be described in detail. However, these embodiments should not be construed as limiting the techniques thereto. The below-described deposition structure of the layers of the semiconductor light-emitting device and the electrode structure are given only for the illustration purpose, and other deposition structures differing therefrom may also be employed. The thickness of each of the layers shown in the drawings is not an actual value, but a conceptual value.

### First Embodiment

### 1. Semiconductor Light-Emitting Device

FIG. 1 is a schematic view of the structure of a light-emitting device 100 according to a first embodiment. As shown in FIG. 1, the light-emitting device 100 is a face-up type semiconductor light-emitting device. The light-emitting device 100 has a plurality of Group III nitride semiconductor layers. The light-emitting device 100 is also an ultraviolet light-emitting device.

As shown in FIG. 1, the light-emitting device 100 has a substrate S1 whose surface polarity is +c, a first oxide film O1, a first Group III nitride layer I1, a second oxide film O2, an n-type contact layer 110, an n-side cladding layer 130, a light-emitting layer 140, a p-side cladding layer 150, a p-type contact layer 160, a transparent electrode TE1, an n-electrode N1, and a p-electrode P1.

The n-type contact layer 110 and the n-side cladding layer 130 are n-type semiconductor layers. The n-type semiconductor layer is a first conductive type first semiconductor layer. The p-side cladding layer 150 and the p-type contact layer 160 are p-type semiconductor layers. The p-type semiconductor layer is a second conductive type second semiconductor layer. The n-type semiconductor layer may include an ud-GaN layer not doped with a dormer or a similar layer. The p-type semiconductor layer may include an ud-GaN layer not doped with an acceptor or a similar layer.

The substrate S1 is an AlN substrate. In FIG. 1, the main surface of the substrate S1 is flat. The main surface of the substrate S1 may have an uneven structure.

The first oxide film O1 is formed on and in direct contact with the main surface of the substrate S1. The first oxide film O1 is a surface oxide film obtained through oxidation of surface AlN of the substrate S1. The first oxide film O1, for example, Al₂O₃ or AlOₓN_{y}, is uniformly obtained on the substrate S1 by oxidizing AlN. When the substrate S1 is made of AlGaN, the first oxide film O1 made of AlₐGa_{b}OₓN_{y} is uniformly obtained on the substrate S1 by oxidizing AlGaN of the surface.

The first Group III nitride layer I1 is formed in direct contact with the first oxide film O1. The first Group III nitride layer I1 is an intermediate layer disposed between the first oxide film O1 and the second oxide film O2. The first Group III nitride layer I1 is made of, for example, AlₓGa₁₋ₓN (0<X≤1).

The second oxide film O2 is formed in direct contact with the first Group III nitride layer I1. The second oxide film O2 is a surface oxide film obtained by oxidizing AlₓGa₁₋ₓN. The second oxide film O2, for example, Al₂O₃, AlOₓN_{y} or AlₐGa_{b}OₓN_{y} is uniformly obtained on the first Group III nitride layer I1 by oxidizing surface AlGaN of the surface. On the second oxide film O2 is formed the n-type contact layer 110 corresponding to the first conductive type first semiconductor layer.

Each thickness of the first oxide film O1 and the second oxide film O2 is preferably in a range from larger than 2 nm to not larger than 100 nm, more preferably in a range from 3 nm to 100 nm. The first and second oxide films O1 and O2 can be uniformly formed on the entire surfaces of the substrate S1 and the first Group III nitride layer I1 in these thickness ranges, respectively. The thickness ranges are also effective enough to perfectly and uniformly invert the polarity of the first Group III nitride layer I1 from the polarity of the substrate and invert the polarity of the n-type contact layer 110 from the polarity of the first Group III nitride layer I1.

The n-type contact layer 110 is provided to form an ohmic contact with the n-electrode N1. The n-type contact layer 110 is formed in direct contact with the second oxide film O2. The n-electrode N1 is disposed on the n-type contact layer 110. The n-type contact layer 110 is made of, for example, n-type GaN.

The n-side cladding layer 130 is a strain relaxation layer for relaxing the stress applied to the light-emitting layer 140. The n-side cladding layer 130 is formed on the n-type contact layer 110. The n-side cladding layer 130 is formed through depositing, for example, Si-doped AlGaN layers. Needless to say, the semiconductor may be made of semiconductor layers having other composition.

The light-emitting layer 140 emits light through recombination of an electron with a hole. The light-emitting layer 140 is formed on the n-side cladding layer 130. The light-emitting layer 140 is formed through repeatedly depositing layer units each formed by depositing a well layer and a barrier layer. That is, the light-emitting layer 140 has a multiple quantum-well (MQW) structure. The light-emitting layer 140 may have a cap layer formed on the well layer. The light-emitting layer 140 may have a single quantum-well structure.

The p-side cladding layer 150 is formed on the light-emitting layer 140. The p-side cladding layer 150 is formed through depositing p-type AlGaN layers. Needless to say, the semiconductor may be made of semiconductor layers having other composition.

The p-type contact layer 160 is provided to form an Ohmic contact with the transparent electrode TE1. The p-type contact layer 160 is formed on the p-side cladding layer 150. The p-type contact layer 160 is made of, for example, Al_{Y}Ga_{1-Y}N (0≤Y≤1).

The transparent electrode TE1 is provided to diffuse current in a light-emitting surface. The transparent electrode TE1 is formed on the p-type contact layer 160. The transparent electrode TE1 is preferably made of at least one selected from a group consisting of ITO, IZO, ICO, ZnO, TiO₂, NbTiO₂, TaTiO₂, and SnO₂. The transparent electrode TE1 may be a blue transparent electrode.

The p-electrode P1 is formed on the transparent electrode TE1. The p-electrode P1 is formed by combining at least one selected from a group consisting of Ni, Au, Ag, Co, and others. Needless to say, other composition may be used. The p-electrode P1 is conductive with the p-type semiconductor layer.

The n-electrode N1 is formed on the n-type contact layer 110. The n-electrode N1 is formed by combining at least one selected from a group consisting of Ni, Au, Ag, Co, Ti, V, and others. Needless to say, other composition may be used. The n-electrode N1 is conductive with the n-type semiconductor layer.

The light-emitting device 100 may include a protective film for protecting the semiconductor layer.

### 2. Oxide Film

### 2-1. Peripheral Structure of Oxide Film

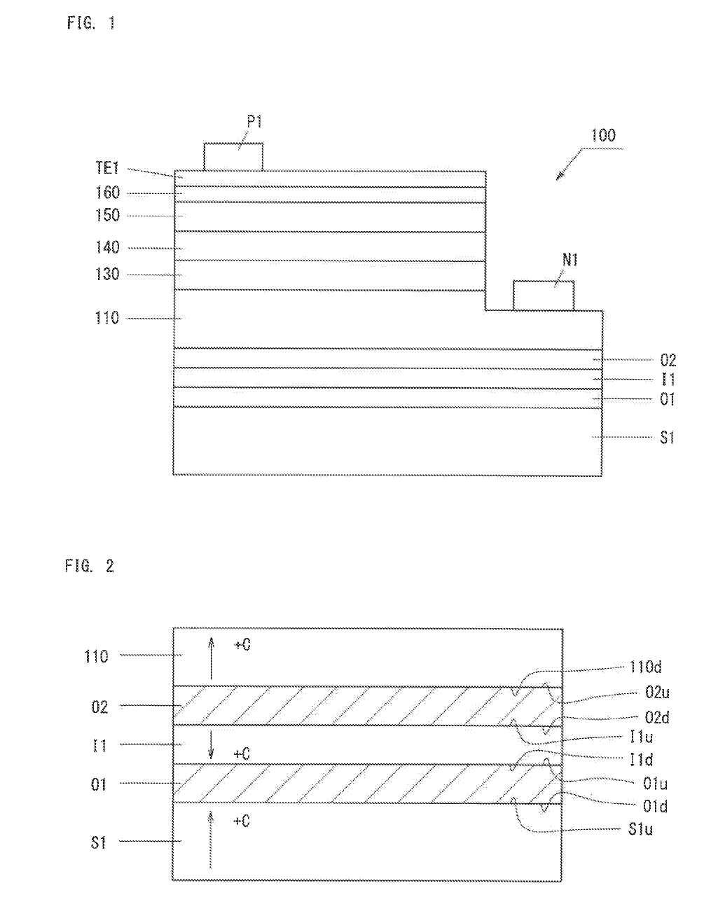

FIG. 2 is an enlarged view drawn by extracting the periphery of the oxide film. As shown in FIG. 2, the substrate S1 has a main surface S1u. The main surface S1u is Al polar surface (+c plain). The first oxide film O1 has a bottom surface O1d and a top surface O1u. The first Group III nitride layer I1 has a bottom surface I1d and a top surface I1u. The second oxide film O2 has a bottom surface O2d and a top surface O2u. The n-type contact layer 110 has a bottom surface 110d.

As shown in FIG. 2, the bottom surface O1d of the first oxide film O1 is in contact with the main surface S1u of the substrate S1. The top surface O1u of the first oxide film O1 is in contact with the bottom surface I1d of the first Group III nitride layer I1.

The bottom surface O2d of the second oxide film O2 is in contact with the top surface I1u of the first Group III nitride layer I1. The top surface O2u of the second oxide film O2 is in contact with the bottom surface 110d of the n-type contact layer 110.

### 2-2. Polarity Inversion in Oxide Film

The first oxide film O1 and the second oxide film O2 are polarity inversion layers. Firstly, the case where there are no oxygen atoms will be described. When there are no oxygen atoms, a pair of a plane on which Al atoms are distributed and a plane on which N atoms are distributed is repeatedly arranged in a c-axis direction.

When the surface (Al surface, i.e., +c plane) of the AlN substrate S1 is uniformly and evenly oxidized, N atoms on the surface of the substrate S1 are placed with O atoms, and an Al−O covalent bond is generated. At this time, O and Al crystals have an octahedral coordination structure. The polarity of the octahedral coordination is determined by the polarity of the AlN substrate S1. Therefore, the polarity of Group III nitride semiconductor being grown on the octahedral crystals of O and Al is opposite to the polarity of the AlN crystal of the substrate S1. Thus, Al—O—Al bond inverts the polarity.

Because of existence of the octahedral crystals of O and Al of the first oxide film O1, the bottom surface I1d of the first Group III nitride layer I1 is Al polar surface (+c plane) and the top surface I1u of the first Group III nitride layer I1 is N polar surface (−c plane). Because of existence of octahedral crystals of O and Al of the second oxide film O2, the bottom surface 110d of the n-type contact layer 110 is N polar surfaces (−c plane). That is, the polarities of the substrate S1, the first Group III nitride layer I1 and the n-type contact layer 110 are Al polarity (+c polarity), N polarity (−c polarity) and Al polarity (+c polarity), respectively, with respect to an upward direction, i.e., a growing direction as shown in FIG. 2.

On the other hand, the first oxide film O1 makes the polarity of the semiconductor thereon change from Al polarity (+c polarity) to N polarity (−c polarity) and the second oxide film O2 makes the polarity of the semiconductor change thereon from N polarity (−c polarity) to Ga or Al polarity (+c polarity) in the growing direction as shown in FIG. 2.

In the above case when the first Group III nitride layer I1 and the n-type contact layer 110 are made of AlGaN (including AlN), the first oxide film O1 and the second oxide film O2 are more effective for inversion of the polarity in the Al composition molar ratio not smaller than 0.5, more preferably not smaller than 0.8.

If the oxidization of the substrate S1 or the first Group III nitride layer I1 is not uniform and perfect on the entire surface, a portion where nitrogen polar surface (−c) is dominant and a portion where Al or Ga polar surface (+c) is dominant are generated in a mixed mode. Even in this case the AlGaN having +c polarity with a smaller molar ratio of Al can laterally grow over the AlGaN having −c polarity in a higher temperature, e.g., not less than 1000° C. As a result if we thickly grow AlGaN of the first Group III nitride layer I1 or the n-type contact layer 110, the AlGaN having +c polarity can be obtained on the entire surface of the substrate S1 or the first Group III nitride layer I1. However since it is difficult that the AlGaN with the Al composition molar ratio not smaller than 0.5 laterally grows even in a higher temperature. As result the oxide film O1 and the oxide film O2 are especially effective to obtain an uniform polarity of AlGaN on the entire surface of the substrate S1 and the first Group III nitride layer I1 in a case of growing the AlGaN with the Al composition molar ratio not smaller than 0.5, more preferably not smaller than 0.8. The oxide films O1 and O2 having a function of polarity inversion are hatched in FIG. 2.

### 2-3. Effect of Polarity Inversion

The AlN substrate is usually taken out from a production apparatus after the production. In that case, the surface of the AlN substrate is partially and naturally oxidized with oxygen in the atmosphere. Because an oxide film is partially formed on the surface of the AlN substrate, a polarity inversion partially occurs on the surface of the AlN substrate. Thus, in the prior art, variation occurs locally in the degree of the polarity inversion. Therefore, when a Group III nitride semiconductor layer is grown on such an AlN substrate, a portion where Al polarity (+c polarity) is dominant and a portion where N polarity (−c polarity) is dominant were sometimes generated in one layer.

On the other hand, in the first embodiment, the polarity of the entire AlN substrate is once inverted by forming the first oxide film O1 containing Al. Thus, coexistence of a portion where Al polarity is dominant and a portion where N polarity is dominant can be suppressed from being generated. Next the polarity of an object semiconductor layer (such as the n-type contact layer 110) is uniformly aligned in the target polarity by the second oxide film O2 containing Al. Therefore, the semiconductor layers have good crystallinity and low impurity concentration in the light-emitting device 100.

### 3. Method for Producing Semiconductor Light-Emitting Device

Next will be described the method for producing the light-emitting device 100 of the first embodiment. The semiconductor layers in the form of crystalline layers are epitaxially formed through metal-organic chemical vapor deposition (MOCVD). The carrier gas employed in the growth of semiconductor layers is hydrogen (H₂), nitrogen (N₂), and a mixture of hydrogen and nitrogen (H₂₊N₂). Ammonia gas (NH₃) is used as a nitrogen source, and trimethylgallium (Ga(CH₃)₃) as a gallium source. Trimethylindium (In(CH₃)₃) is used as an indium source, and trimethylaluminum (Al(CH₃)₃) is used as an aluminum source. Silane (SiH₄) is used as an n-type dopant gas, and bis(cyclopentadienyl)magnesium (Mg(C₅H₅)₂) is used as a p-type dopant gas. Gases other than the above may also be used.

### 3-1. Cleaning of Substrate

A substrate S1 is cleaned with H₂ gas. The substrate temperature is approximately 1100° C. Needless to say, other substrate temperature may be used.

### 3-2. First Oxide Film Formation Step

Subsequently, a first oxide film O1 is formed on the substrate S1 as a surface oxide film. An oxide film containing Al atoms, N atoms, and O atoms is formed as the first oxide film O1. For that, the substrate S1 is heated in a temperature range from 200° C. to 400° C. in the atmosphere including oxygen. The heating temperature may be higher than 25° C. Alternatively, the substrate S1 may be left in the atmosphere or an oxygen atmosphere outside the MOCVD furnace.

### 3-3. First Group III Nitride Layer Formation Step

Next, a first Group III nitride layer I1 is formed on the first oxide film O1. At that time, MOCVD or sputtering may be employed. The substrate temperature is within a range of 850° C. to 1200° C. In this temperature range, AlN is preferably grown. The polarity of the AlN which is grown on the first oxide film O1 is decided by the polarity of the octahedral crystals of O and Al of the first oxide film O1. The polarity of the octahedral crystals of O and Al is opposite to the polarity of the substrate. Accordingly, the polarity of the AlN which is grown on the substrate having Al polarity (+c polarity) is uniformly N polarity (−c polarity).

### 3-4. Second Oxide Film Formation Step

Then, a second oxide film O2 is formed on the first Group III nitride layer I1 as a surface oxide film. An oxide film containing Al atoms, N atoms, and O atoms is formed as the second oxide film O2. For that, the substrate S1 on which the first oxide film O1 and the first Group III nitride layer I1 the substrate S1 is heated in a temperature range from 200° C. to 400° C. in the atmosphere including oxygen. The heating temperature may be higher than 25° C. Alternatively, the substrate S1 may be left in the atmosphere or an oxygen atmosphere outside the MOCVD furnace.

### 3-5. First Semiconductor Layer Formation Step

3-5-1. n-Type Contact Layer Formation Step

Next, an n-type contact layer 110 is formed on the second oxide film O2. The substrate temperature is 900° C. to 1140° C. In this temperature range, GaN of the n-type contact layer 110 is preferably grown. The polarity of the GaN which is grown on the second oxide film O2 is decided by the polarity of the octahedral crystals of O and Al of the second oxide film O2. The polarity of the octahedral crystals of O and Al is opposite to the polarity of the first Group III nitride layer I1. Accordingly, the polarity of the GaN which is grown on the first Group III nitride layer I1 having N polarity (−c polarity) is uniformly Ga polarity (+c polarity), i.e., Group III metal polarity. Therefore, the semiconductor layer has a good crystallinity in the light-emitting device 100 because of uniform polarity in the entirety of the semiconductor layer.

The n-type contact layer 110 may be made of AlGaN (including AlN) with the Al composition molar ratio not smaller than 0.5, more preferably not smaller than 0.8. In this case the second oxide film O2 is especially effective for obtaining uniform polarity because of above described reason.

3-5-2. n-Side Cladding Layer Formation Step

Subsequently, an n-side cladding layer 130 is formed on the n-type contact layer 110. For that, Si-doped AlGaN layers are deposited.

### 3-6. Light-Emitting Layer Formation Step

Next, a light-emitting layer 140 is formed on the n-side cladding layer 130. For that, layer units are repeatedly deposited each formed by depositing a well layer and a barrier layer. A cap layer may be formed after the formation of the well layer.

### 3-7. Second Semiconductor Layer Formations Step

3-7-1. p-Side Cladding Layer Formation Step

Next, a p-side cladding layer 150 is formed on the light-emitting layer 140. P-type AlGaN layers are deposited.

3-7-2. p-Type Contact Layer Formation Step

Subsequently, a p-type contact layer 160 is formed on the p-side cladding layer 150.

### 3-8. Transparent Electrode Formation Step

Next, a transparent electrode TE1 is formed on the p-type contact layer 160.

### 3-9. Electrode Formation Step

Next, a p-electrode P1 is formed on the transparent electrode TE1. A part of the semiconductor layers is removed from the p-type contact layer 160 side using a laser or by etching to expose the n-type contact layer 110. Then, an n-electrode N1 is formed on the exposed portion of the n-type contact layer 110. The step of forming the p-electrode P1 may be performed before the step of forming the n-electrode N1, or the step of forming the n-electrode N1 may be performed before the step of forming the p-electrode P1.

### 3-10. Other Steps

In addition to the steps described above, other steps such as a heat treatment step and an insulating film formation step may be performed. Through the above, the light-emitting device 100 shown in FIG. 1 is produced.

### 4. Variations

### 4-1. Flip Chip

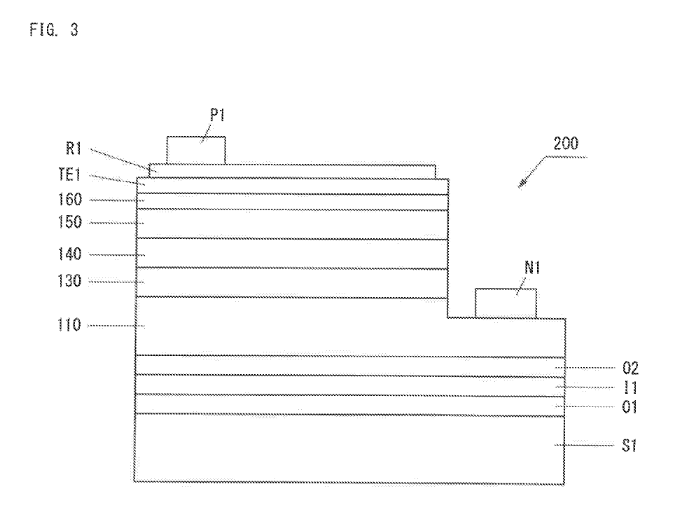

FIG. 3 is a schematic view of the structure of a light-emitting device 200 according to a variation of the first embodiment. The light-emitting device 200 is a flip-chip type semiconductor light-emitting device. The light-emitting device 200 has a reflective layer R1. The reflective layer R1 is disposed between the transparent electrode TE1 and the p-electrode P1.

### 4-2. Substrate Material

In the first embodiment, the substrate S1 is an AlN substrate. However, the substrate S1 may be an AlGaN substrate. The substrate may also be a template substrate prepared by forming AlN or AlGaN on a sapphire substrate.

### 4-3. First Oxide Film Material

In the first embodiment, the first oxide film O1 is made of AlON. However, the first oxide film O1 may be made of oxidized AlGaN. That is, the first oxide film O1 contains Al atoms, N atoms, and O atoms.

### 4-4. First Group III Nitride Layer Material

In the first embodiment, the first Group III nitride layer I1 may also be made of AlN, AlGaN or GaN.

### 4-5. Second Oxide Film Material

In the first embodiment, the second oxide film O2 is made of AlON. However, the second oxide film O2 may be made of oxidized AlGaN. That is, the second oxide film O2 contains Al atoms, N atoms, and O atoms.

### 4-6. Top Layer of Second Oxide Film

In the first embodiment, the n-type contact layer 110 is formed on the second oxide film O2. However, any Group III nitride layer may be formed between the second oxide film O2 and the n-type contact layer 110.

### 4-7. Layered Structure of Semiconductor Layer

In the first embodiment, the n-type contact layer 110, the n-side cladding layer 130, the light-emitting layer 140, the p-side cladding layer 150, and the p-type contact layer 160 are formed on the second oxide film O2. However, needless to say, the layered structure other than the above may also be used. The layers of the above layered structure may have a deposition structure other than that described in the first embodiment.

### 4-8. Polarity Inversion

In the first embodiment, the surface S1u of the substrate S1 on which the first Group III nitride layer I1 is grown is the Al polar surface (+c plane). The polarity of the first Group III nitride layer I1 is N polarity (−c polarity) along the growing direction. And the polarity of the n-type contact layer 110 grown on the second oxide film O2 is uniformly Ga or Al polarity (+c polarity) along the growing direction. However, the polarity may be inverted. That is, the top surface of the substrate S1 may be the N polar surface (−c plane). The polarity of the first Group III nitride layer I1 may have the Al or Ga polarity (+c polarity) and the polarity of the n-type contact layer 110 may have the N polarity (−c polarity).

### 4-9. Emission Wavelength

The light-emitting device 100 of the first embodiment is an ultraviolet light-emitting device. The present invention is effective especially for an ultraviolet light-emitting device in which a substrate and all epitaxial layers are made of AlGaN including AlN except a well layer of a light-emitting layer may include In. However, the light-emitting device may emit light of wavelength other than ultraviolet ray.

### 4-10. Combination

The above variations may be freely combined.

### 5. Summary of the First Embodiment

As described above, the light-emitting device 100 of the first embodiment includes the first oxide film O1, the first Group III nitride layer I1, and the second oxide film O2. The first oxide film O1 and the second oxide film O2 invert the polarity of the base layer thereunder. Therefore, the mixture of Group III polar surface and N polar surface can be suppressed in the semiconductor layer being grown. That is, the semiconductor layer has good crystallinity.

Notably, the aforementioned embodiments are given for the illustration purpose. Thus, needless to say, various modifications and variations can be made, so long as they fall within the scope of the present technique. The semiconductor layer growth technique is not limited to metal-organic chemical vapor deposition (MOCVD). Other similar techniques may be employed, as long as they employ carrier gas in crystal growth. Alternatively, the semiconductor layers may be formed through another epitaxial growth technique such as liquid phase epitaxy or molecular beam epitaxy.

What is claimed is:

1. A Group III nitride semiconductor light-emitting device, including:
a substrate;
a first oxide film formed in contact with the substrate;
a first Group III nitride layer formed in contact with the first oxide film;
a second oxide film formed in contact with the first Group III nitride layer;
a first conductive type first semiconductor layer formed on the second oxide film;
a light-emitting layer formed on the first semiconductor layer; and
a second conductive type second semiconductor layer formed on the light-emitting layer,
wherein the substrate is an AlN substrate or AlGaN substrate;
the first oxide film contains Al atoms, N atoms, and O atoms;
the first Group III nitride layer comprises AlN or AlGaN; and
the second oxide film contains Al atoms, N atoms, and O atoms.

2. The Group III nitride semiconductor light-emitting device according to claim 1, wherein the first oxide film is an oxidized surface of the substrate and the second oxide film is an oxidized surface of the first Group III nitride layer.

3. The Group III nitride semiconductor light-emitting device according to claim 1, wherein a polarity of the first conductive type first semiconductor layer is equal to a polarity of the substrate.

4. The Group III nitride semiconductor light-emitting device according to claim 1, wherein the substrate is made of AlN and the first Group III nitride layer is made of AlN.

5. The Group III nitride semiconductor light-emitting device according to claim 2, wherein the substrate is made of AlN and the first Group III nitride layer is made of AlN.

6. The Group III nitride semiconductor light-emitting device according to claim 4, wherein the first oxide film is made of AlON, and the second oxide film is made of AlON.

7. The Group III nitride semiconductor light-emitting device according to claim 1, wherein each thickness of the first oxide film and the second oxide film is in a range from 3 nm to 100 nm.

8. The Group III nitride semiconductor light-emitting device according to claim 2, wherein each thickness of the first oxide film and the second oxide film is in a range from 3 nm to 100 nm.

9. The Group III nitride semiconductor light-emitting device according to claim 1, wherein an Al composition ratio of the first Group III nitride layer is not smaller than 0.5.

10. The Group III nitride semiconductor light-emitting device according to claim 7, wherein an Al composition ratio of the first Group III nitride layer is not smaller than 0.5.

11. The Group III nitride semiconductor light-emitting device according to claim 1, wherein an Al composition ratio of the first conductive type first semiconductor layer is not smaller than 0.5.

12. The Group III nitride semiconductor light-emitting device according to claim 7, wherein an Al composition ratio of the first conductive type first semiconductor layer is not smaller than 0.5.

13. A method for producing a Group III nitride semiconductor light-emitting device, the method comprising:
forming a first oxide film on a substrate;
forming a first Group III nitride layer on the first oxide film;
forming a second oxide film on the first Group III nitride layer;
forming a first conductive type first semiconductor layer on the second oxide film;
forming a light-emitting layer on the first semiconductor layer; and
forming a second conductive type second semiconductor layer on the light-emitting layer,
wherein an AlN substrate or AlGaN substrate is employed as the substrate;
In the forming a first oxide film, an oxide film containing Al atoms, N atoms, and O atoms is formed as the first oxide film;
In the forming a first Group III nitride layer, an AlN layer or AlGaN layer is formed as the first Group III nitride layer;
In the forming a second oxide film, an oxide film containing Al atoms, N atoms, and O atoms is formed as the second oxide film.

14. The method for producing a Group III nitride semiconductor light-emitting device according to claim 13, wherein each thickness of the first oxide film and the second oxide film is in a range from 3 nm to 100 nm.

15. The method for producing a Group III nitride semiconductor light-emitting device according to claim 14, wherein an Al composition ratio of the first Group III nitride layer is not smaller than 0.5.

16. The method for producing a Group III nitride semiconductor light-emitting device according to claim 14, wherein an Al composition ratio of the first conductive type first semiconductor layer is not smaller than 0.5.
